(19) United States
(12) Patent Application Publication
(10) Pub. No.: US 2015/0333057 A1
(43) Pub. Date: Nov. 19, 2015

(54) MEANDER RESISTOR

(71) Applicant: GLOBALFOUNDRIES Inc., Grand Cayman (KY)

(72) Inventors: Jan Hoentschel, Dresden (DE); Stefan Flachowsky, Dresden (DE); Andreas Kurz, Dresden (DE); Sven Beyer, Dresden (DE); Wolfgang Buchholtz, Radebeul (DE)

(73) Assignee: GLOBALFOUNDRIES Inc., Grand Cayman (KY)

(21) Appl. No.: 14/276,515

(22) Filed: May 13, 2014

(51) Int. Cl. H01L 27/07; H01L 49/02

(52) U.S. Cl. CPC H01L 27/0738; H01L 28/20

(57) ABSTRACT

The present disclosure relates to a semiconductor structure comprising a resistor, at least part of the resistor forming a meandering shape in a vertical direction with respect to a substrate of the semiconductor structure. The disclosure further relates to a semiconductor manufacturing process comprising a step for realizing at least one first fin, and a step for realizing a resistor comprising a meandering shape in a vertical direction based on the at least one first fin.

### BACKGROUND OF THE INVENTION

1. Field of the Invention

Generally, the present disclosure relates to highly sophisticated semiconductor structures, in particular to a resistor which is structured so as to use a reduced surface, and to a manufacturing method thereof. Further, the disclosure relates to the integration of such resistors in a manufacturing flow also optionally comprising the manufacturing of vertically arranged transistors, such as FinFETS.

2. Description of the Related Art

The fabrication of advanced integrated circuits, such as CPUs, storage devices, application specific integrated circuits (ASICs) and the like, requires the formation of a large number of circuit elements on a given chip area according to a specified circuit layout. Among the various elements, resistors are often needed.

Planar resistors, obtained by depositing a film of material onto the wafer, have been known. The deposited material may be of several kinds, but resistors, in particular those at the gate level, have generally been manufactured from polysilicon.

In view of further device scaling based on well-established materials, new transistor configurations have been proposed, in which a “three dimensional” architecture is provided in an attempt to obtain a desired channel width, while, at the same time, superior controllability of the current flow through the channel is preserved. To this end, so-called FinFETs have been proposed in which a thin sliver or fin of silicon is formed in a thin active layer of a silicon-on-insulator (SOI) or a standard silicon substrate, wherein, on both sidewalls and, if desired, on a top surface, a gate dielectric material and a gate electrode material are provided, thereby realizing a multiple gate transistor whose channel may be fully depleted.

FinFETs generally require the use of so-called high-k metal gates, implying that the material for the gate insulator is a high-k material and that a metal is used for the gate itself. This, in turn, implies that the polysilicon, which was previously employed for the manufacturing of resistors at the gate level, may not be available in the process flow any longer, and may be replaced by the metal used for the gate.

Metal is, however, less suitable for realizing resistors, in particular resistors having high resistance values, as metal generally has a conductivity higher than polysilicon.

As the resistors are generally realized by a flat layer of material, the larger area resulting from the use of metal instead of polysilicon has a directly negative impact on the surface area of the wafer occupied by the resistor. As the surface area of the wafer used by each chip is directly related to the price thereof, it is important to limit use of a wafer's surface area as much as possible.

Even if a material other than metal is used for the gate of the FinFET and for the resistor, or for the resistor alone, a flat resistor still has the disadvantage of using a large surface area, thus increasing the costs for the chip carrying the resistor.

In view of the situation described above, the present disclosure relates to semiconductor structures and manufacturing techniques thereof comprising a resistor which is configured so as to occupy a small wafer's surface area and optionally to be made at the same level of a transistor gate.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure solves the above-mentioned problems by using a vertically structured meander resistor. In particular, the resistor may be provided with a plurality of vertical resistive surfaces, connected to each other in a meander manner. In an embodiment provided with, for instance, three vertical surfaces, the top section of a first vertical surface is connected to the top section of a neighboring second vertical surface, while the bottom section of the second vertical surface is connected to the bottom of a third vertical surface, neighboring the second vertical surface. In this manner, the resistor realized by the three vertical surfaces, more precisely starting at the bottom of the first vertical surface and ending at the top of the third vertical surface, has a length corresponding to the combined length of the three vertical surfaces, while the area occupied on the wafer's horizontal surface is only corresponding to the thickness of the three vertical surfaces, and to the length of the parts connecting the first to the second and the second to the third vertical surfaces.

In other words, as the resistor develops in the vertical direction instead of the horizontal one, it is possible to achieve any desired length with minimum surface area consumption. This may not only compensate for the increased length necessary due to the use of a metallic layer instead of a polysilicon one, but can also result in a vertical meander metallic resistor according to the present invention occupying a surface area smaller than a horizontal polysilicon resistor having the same nominal resistance value.

One illustrative method disclosed herein may relate to a semiconductor structure comprising a resistor, at least part of the resistor forming a meandering shape in a vertical direction with respect to a substrate of the semiconductor structure.

One further illustrative method disclosed herein may relate to a semiconductor manufacturing process comprising a step for realizing at least one first fin, and a step for realizing a resistor comprising a meandering shape in a vertical direction based on the at least one first fin.

Thanks to the above-mentioned approaches, even when using a metal layer, such as one used for the gate of FinFETs, it is possible to obtain required resistance levels, by using the appropriate length of metal layer, without negatively impacting the amount of wafer's surface used. This optionally makes it possible to use the same metallic layer for the manufacturing of the resistor and for the manufacturing of the gate of the FinFETs, thus allowing the manufacturing of the resistor by using only process steps already present in the FinFET manufacturing line.

Still further, the vertical meandering of the resistor may be achieved by using vertical fins as supporting structures. As the tools for realizing the vertical fins are already part of the manufacturing line, no additional costs are needed. Still further, the fins acting as support structure for the resistors and those acting as channels for the FinFETs could be realized in parallel, so as to limit the amount of process steps required.

Additionally, as the resistor is realized at the bottom layer of the semiconductor stack, the vertical meandering can be much more exploited than at higher levels in the semiconductor stack. That is, the vertical dimension of the vertical surfaces is limited on their top part by the placement of interconnecting layers and others, but can be extended as much as desired on their bottom part, since the substrate has usually a thickness several order of magnitude bigger than the thickness of the functional layers realized thereon.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a semiconductor structure, according to illustrative embodiments;

FIG. 1b schematically illustrates a cross-sectional view along section A-A′ of FIG. 1a, according to illustrative embodiments;

FIG. 2a schematically illustrates a top view of a semiconductor structure, according to illustrative embodiments;

FIG. 2b schematically illustrates a cross-sectional view along section A-A′ of FIG. 2a, according to illustrative embodiments;

FIG. 3a schematically illustrates a top view of a semiconductor structure, according to illustrative embodiments;

FIG. 3b schematically illustrates a cross-sectional view along section A-A′ of FIG. 3a, according to illustrative embodiments;

FIG. 4a schematically illustrates a top view of a semiconductor structure, according to illustrative embodiments;

FIG. 4b schematically illustrates a cross-sectional view along section A-A′ of FIG. 4a, according to illustrative embodiments;

FIG. 5a schematically illustrates a top view of a semiconductor structure, according to illustrative embodiments;

FIG. 5b schematically illustrates a cross-sectional view along section A-A′ of FIG. 5a, according to illustrative embodiments;

FIG. 6a schematically illustrates a top view of a semiconductor structure, according to illustrative embodiments;

FIG. 6b schematically illustrates a cross-sectional view along section A-A′ of FIG. 6a, according to illustrative embodiments;

FIG. 7a schematically illustrates a top view of a semiconductor structure, according to illustrative embodiments;

FIG. 7b schematically illustrates a cross-sectional view along section A-A′ of FIG. 7a, according to illustrative embodiments;

FIG. 8a schematically illustrates a top view of a semiconductor structure, according to illustrative embodiments;

FIG. 8b schematically illustrates a cross-sectional view along section A-A′ of FIG. 8a, according to illustrative embodiments;

FIG. 9a schematically illustrates a top view of a semiconductor structure, according to illustrative embodiments;

FIG. 9b schematically illustrates a cross-sectional view along section A-A′ of FIG. 9a, according to illustrative embodiments;

FIG. 10a schematically illustrates a top view of a semiconductor structure, according to illustrative embodiments;

FIG. 10b schematically illustrates a cross-sectional view along section A-A′ of FIG. 10a, according to illustrative embodiments;

FIG. 11a schematically illustrates a top view of a semiconductor structure, according to illustrative embodiments;

FIG. 11b schematically illustrates a cross-sectional view along section A-A′ of FIG. 11a, according to illustrative embodiments;

FIG. 11a-bis schematically illustrates a top view of a semiconductor structure, according to illustrative embodiments;

FIG. 11b-bis schematically illustrates a cross-sectional view along section A-A′ of FIG. 11a-bis, according to illustrative embodiments;

FIG. 12a schematically illustrates a top view of a semiconductor structure, according to illustrative embodiments;

FIG. 12b schematically illustrates a cross-sectional view along section A-A′ of FIG. 12a, according to illustrative embodiments;

FIG. 13a schematically illustrates a top view of a semiconductor structure, according to illustrative embodiments; and

FIG. 13b schematically illustrates a cross-sectional view along section A-A′ of FIG. 13a, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various embodiments of the invention are described below. In the interest of clarity, not all features of actual implementations are described in the specification. It will, of course, be appreciated that, in the development of any such actual embodiments, numerous implementations and specific decisions must be made to achieve the developer's specific goals, such as compliance with system-related and business-related constraints, which will vary from one implementation to another. Moreover, it will be appreciated that such a development might, therefore, be complex and time consuming, but would nevertheless be a routine undertaking for those of ordinary skill in the art having the benefits of this disclosure.

The following embodiments are described in sufficient detail to enable those skilled in the art to make use of the invention. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it will be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

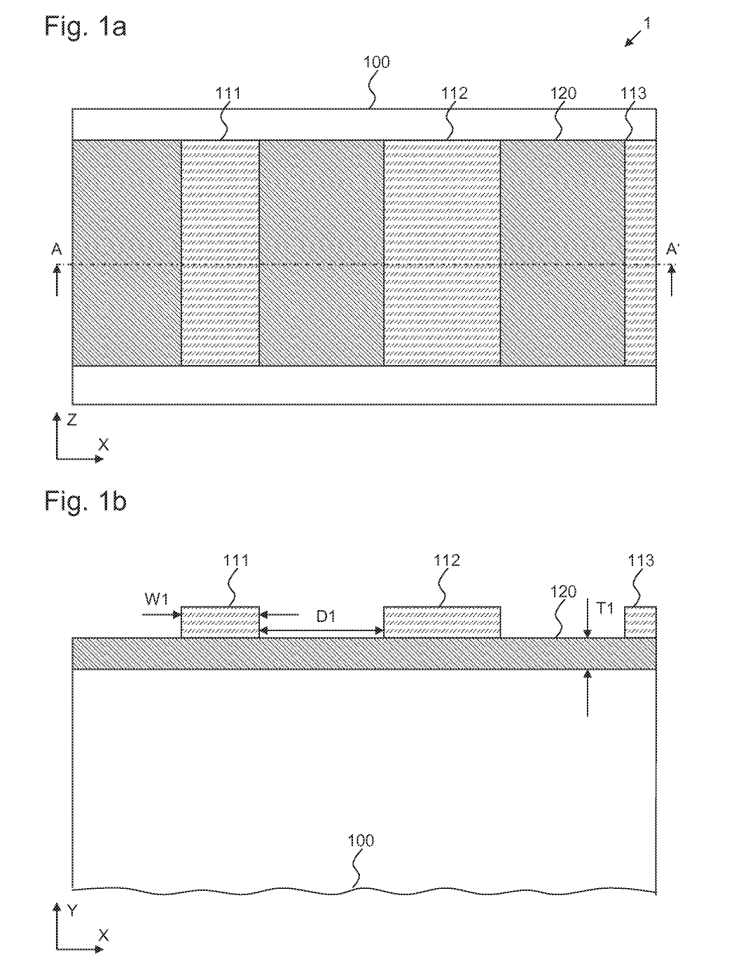

FIG. 1a illustrates a top view of a semiconductor structure 1 while FIG. 1b illustrates a cross-sectional view of the semiconductor structure 1 taken along line A-A′ of FIG. 1a.

As can be seen in FIGS. 1a and 1b, the semiconductor structure 1 comprises a substrate 100, for instance a silicon substrate, silicon-on-insulator (SOI) substrate, a silicon/germanium (SiGe) substrate, or any other substrate which can be used in semiconductor manufacturing. On the substrate 100, a hardmask layer 120 is realized. The hardmask layer 120 could be, for instance, a silicon nitride (SiN) layer or an SiO2 hardmask having a thickness T1 comprised, for instance, in the range of 30-100 nm or with a preferred value of 40 nm. On top of the hardmask layer 120, a plurality of structures 111-113 are realized. The structures 111-113 could be realized, for instance, by using a photolithographic resist or with any other deposition technology, such as 3D printing, nanomolding, etc. The structures can have various widths and be separated from each other by various distances. An exemplary value for the illustrated width W1 may be in the range of, for instance, 20-40 nm or have a preferred value of 27 nm. An exemplary value for the illustrated distance D1 may be, for instance, in the range of 90-130 nm or have a value of 100 nm. As it will be clear from the following description, these values are indicative only and the skilled person will know how to modify them, in particular when the following manufacturing steps are taken into account, so as to obtain structures, generally referred to as “spacers” or “sidewalls,” used for the subsequent fabrication of vertical structures, generally referred to as “fins,” in the substrate 100.

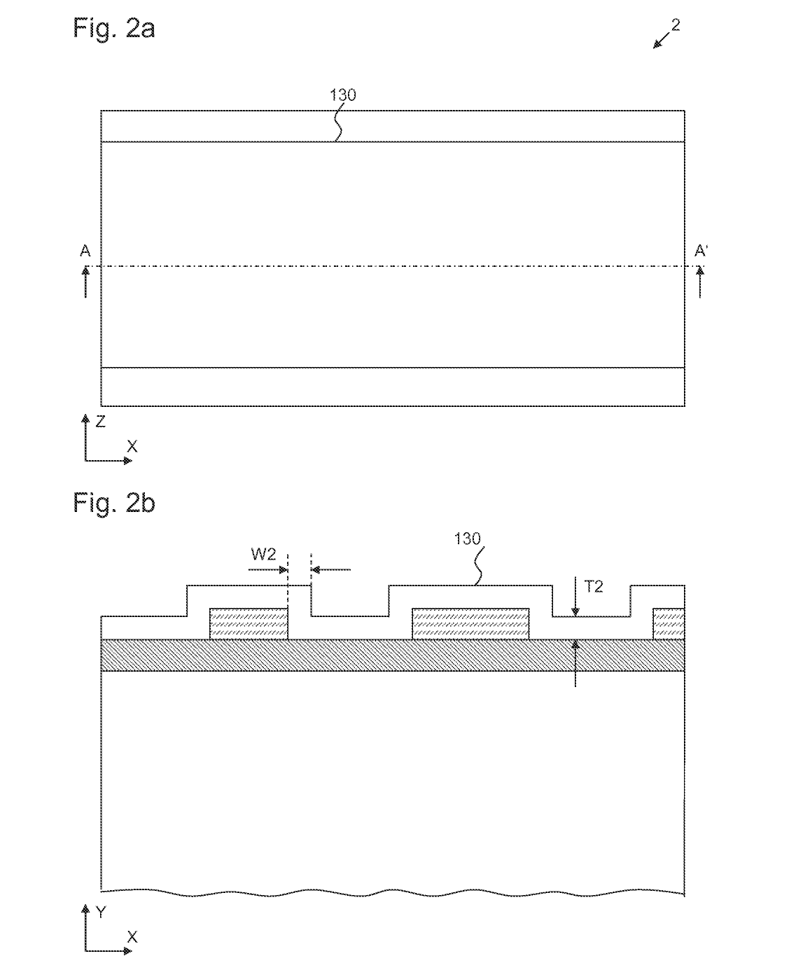

Although not shown in FIGS. 1a-1b, a well isolation implant could optionally be realized at this step, before carrying out the steps of FIGS. 2a-2b. In particular, the well isolation implant could be a deep n and/or p well isolation implant(s) for leakage reduction.

FIGS. 2a and 2b schematically illustrate a semiconductor structure 2 resulting from further processing of the semiconductor structure 1. The views along which FIGS. 2a and 2b have been taken correspond to the views of FIGS. 1a and 1b, respectively. More specifically, as can be seen in FIGS. 2a and 2b, a sidewall layer 130 is realized on top of the semiconductor structure 1, thus resulting in the semiconductor structure 2. The sidewall layer 130 is also usually known as a spacer. The sidewall layer 130 may have a thickness T2, for instance, in the range of 20-30 nm or with a preferred value of 25 nm. In this manner, the sidewall layer 130 creates vertical walls at the edge of each of the structures 111-113 having a width W2, for instance, in the range of 20-30 nm or having a preferred value of 25 nm. The vertical walls of the sidewall layer 130 are thereafter used in what is usually referred to as a “sidewall image transfer” (SIT) process for the subsequent realization of vertical fins in the substrate 100.

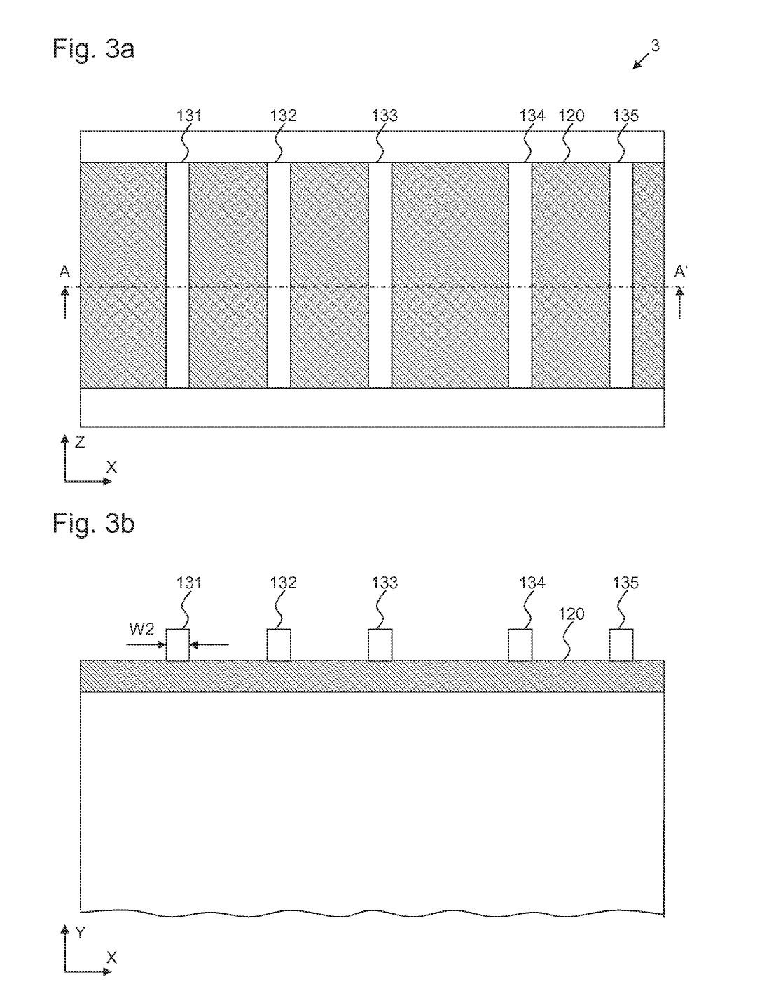

FIGS. 3a and 3b schematically illustrate a semiconductor structure 3 resulting from further processing of the semiconductor structure 2. The views along which FIGS. 3a and 3b have been taken correspond to the views of FIGS. 1a and 1b, respectively. As can be seen in FIGS. 3a and 3b, after an etching step is performed on the semiconductor structure 2, the sidewall layer 130 results in a plurality of sidewalls, or spacers, 131-135 left on the hardmask layer 120. The advantage of this manufacturing approach, known as sidewall image transfer, consists in the fact that the sidewalls 131-135 can each have a width W2 much thinner than the width W1 of the structures 111-113 realized, for instance, by a photolithographic step. Also, since the thickness W2 is controlled based on the growth of the sidewall layer 130 and not based on a lithographic process, it can be more precisely controlled and uniform on the entire wafer.

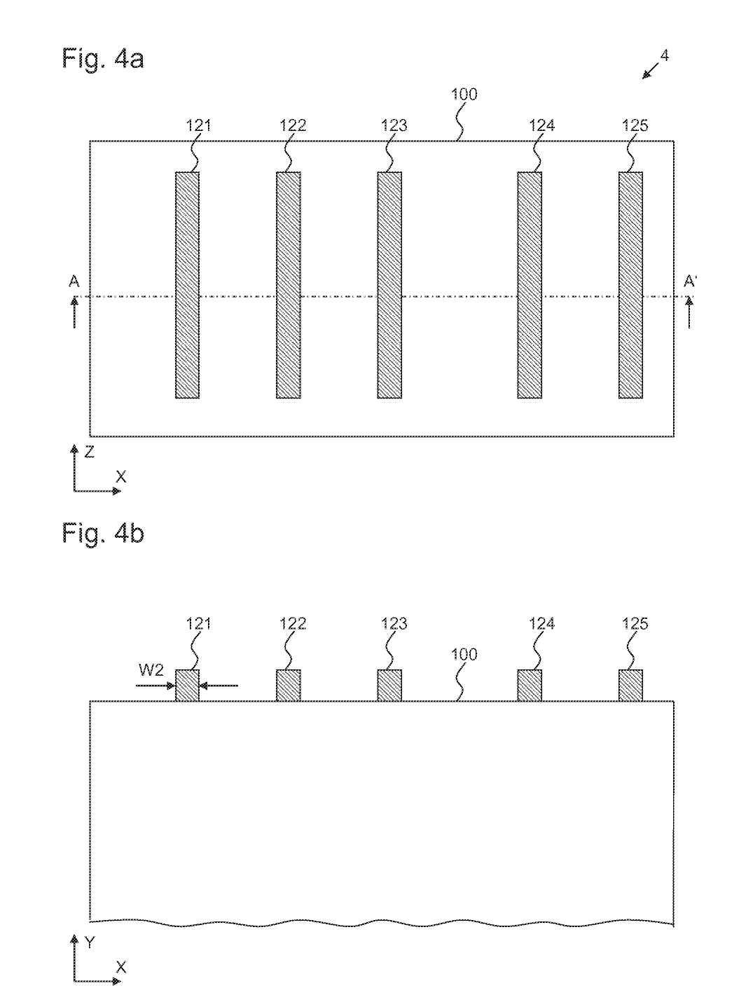

FIGS. 4a and 4b schematically illustrate a semiconductor structure 4 resulting from further processing of the semiconductor structure 3. The views along which FIGS. 4a and 4b have been taken correspond to the views of FIGS. 1a and 1b, respectively. As can be seen in FIGS. 4a and 4b, the semiconductor structure 4 results from the semiconductor structure 3 after an etching step during which the regions of the hardmask layer 120 not protected by sidewalls 131-135 are removed and after a subsequent removal step of the sidewalls 131-135, thus resulting in the realization of hardmask spacers 121-125. The location and dimensions of the hardmask spacers 121-125 along directions X and Z, therefore, substantially correspond to the location and dimensions of the sidewalls 131-135. The hardmask spacers 121-125 may be used as a hard mask for etching the substrate layer 100 underneath, thus resulting in the creation of vertical fins within the substrate layer 100, as will be described with reference to the following figures.

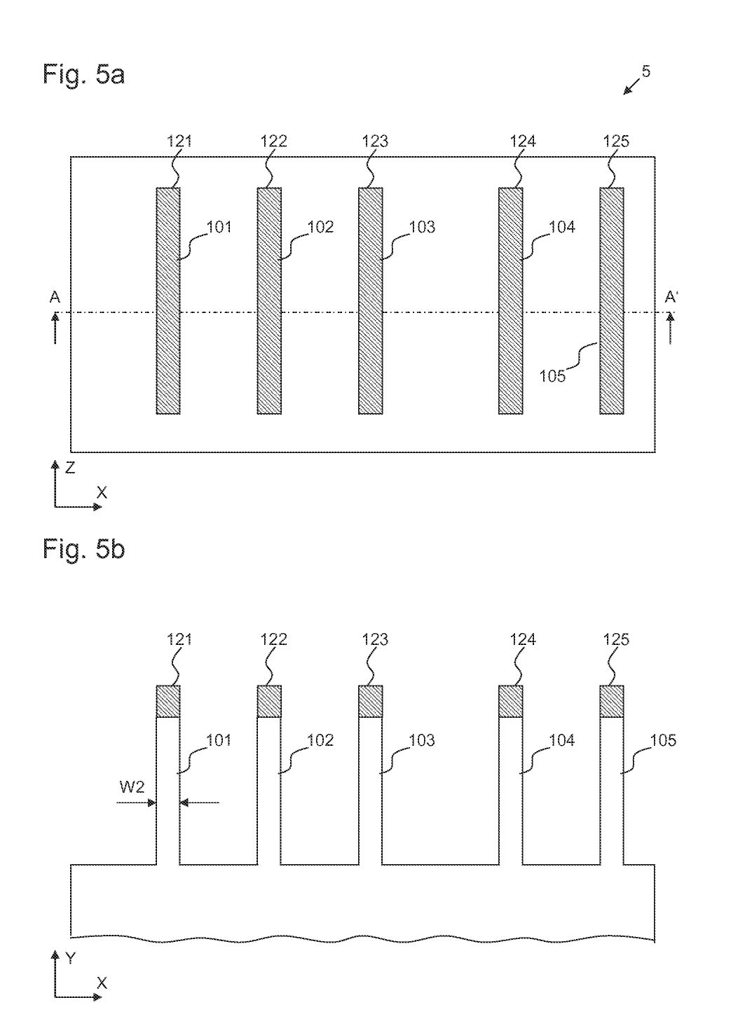

FIGS. 5a and 5b schematically illustrate a semiconductor structure 5 resulting from further processing of the semiconductor structure 4. The views along which FIGS. 5a and 5b have been taken correspond to the views of FIGS. 1a and 1b, respectively. As can be seen in FIGS. 5a and 5b, the semiconductor structure 5 results from the semiconductor structure 4 after an etching step of the semiconductor substrate 100, resulting in the creation of vertical fins 101-105 in the areas of the substrate 100 below the hardmask spacers 121-125. The location and dimensions of the vertical fins 101-105 along directions X and Z, therefore, substantially correspond to the location and dimensions of the hardmask spacers 121-125.

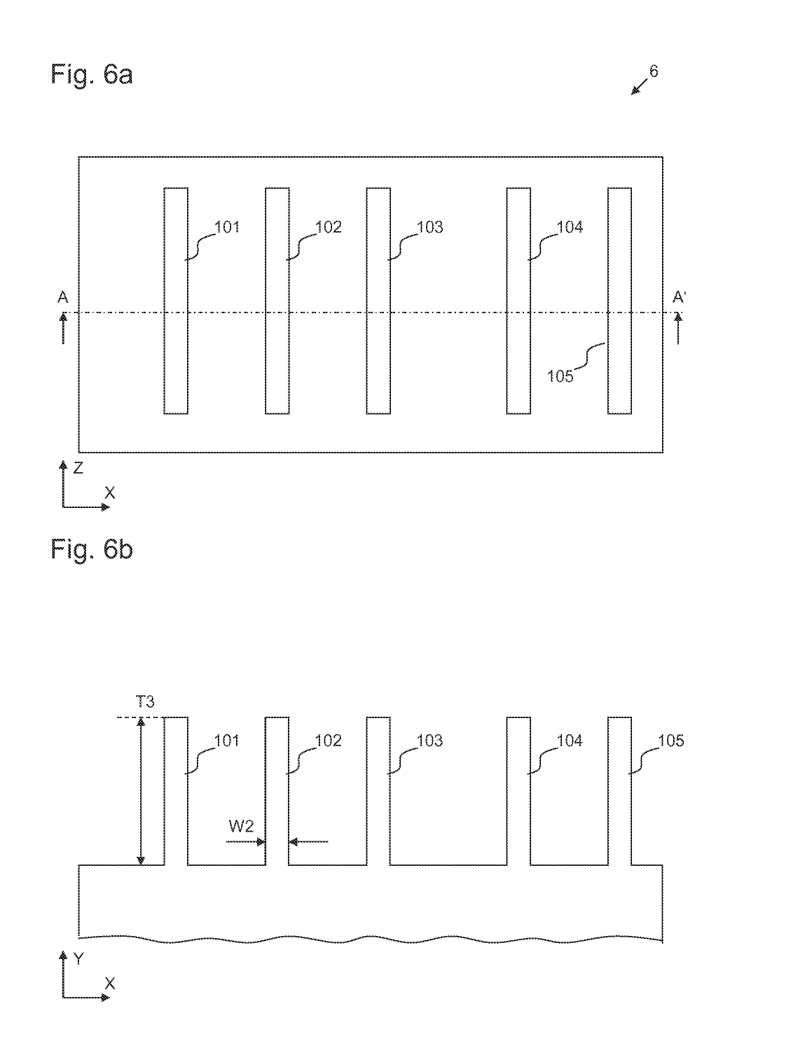

FIGS. 6a and 6b schematically illustrate a semiconductor structure 6 resulting from further processing of the semiconductor structure 5. The views along which FIGS. 6a and 6b have been taken correspond to the views of FIGS. 1a and 1b, respectively. Semiconductor structure 6 results from semiconductor structure 5 after a subsequent etching step consisting in the removal of hardmask spacers 121-125 from the top of respective fins 101-105. At this stage, the fins 101-105 are then finalized and can have a height T3 in the Y direction of, for instance, in the range of 80-120 nm or a preferred value of 100 nm. The width of fins 101-105 is substantially similar to the width W2 of the sidewalls 131-135 and of the hardmask spacers 121-125.

It should be noted here that, as it will be clear to those skilled in the art, this is not the only possible manufacturing method for realizing the vertical fins 101-105 in a semiconductor substrate 100. In alternative embodiments, the fins could be vertically grown on top of the substrate 100. Still alternatively, they may be realized by a standard lithographic approach. For the purpose of the present invention, any technology that can realize vertical structures on a substrate may be employed, while the one described above is only one possible implementation.

Moreover, although five vertical fins 101-105 have been illustrated in the present embodiment, the present invention is not limited thereto and any number of fins may be realized instead, as it will be clear to those skilled in the art.

Although not illustrated, at this point, an optional fin isolation implant could be carried out. In one embodiment, a fin diode may be created for avoiding a leakage down through the fin into the substrate. This could be achieved, for instance, by a fin isolation implantation.

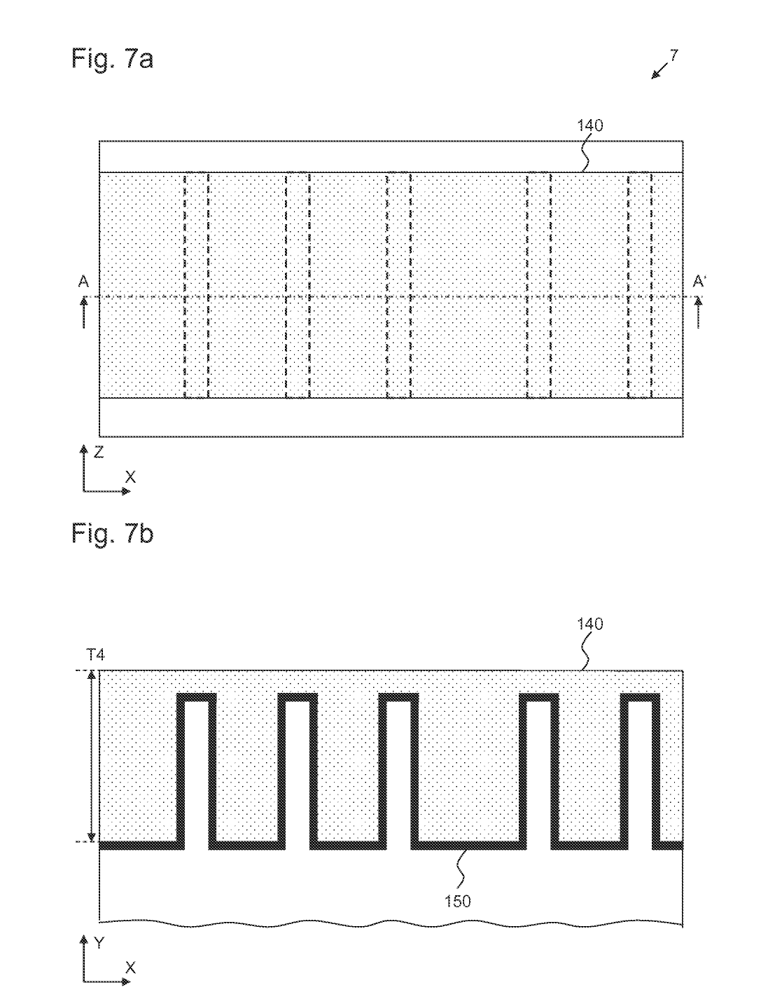

FIGS. 7a and 7b schematically illustrate a semiconductor structure 7 resulting from further processing of the semiconductor structure 6. The views along which FIGS. 7a and 7b have been taken correspond to the views of FIGS. 1a and 1b, respectively. In FIG. 7a, as well as the following corresponding figures from the same point of view, the location of the fins 101-105 has been illustrated in dashed lines, so as to clarify the positional relationship of the various layers placed on top of it.

As can be seen in FIGS. 7a and 7b, the semiconductor structure 7 differs from the semiconductor structure 6 due to the presence of an insulating layer 150 and a conducting layer 140. In particular, the insulating layer 150 is deposited on the semiconductor substrate 100, thus resulting in a conformal deposition over the surfaces of the semiconductor substrate 100 and the fins 101-105. The thickness of the insulating layer 150 may be, for instance, in the range of 3-10 nm or have a preferred value of 4 nm. The insulating layer 150 may be realized, for instance, by a conformal deposition, such as an atomic layer deposition (ALD), of an insulating material, such as silicon oxide (SiO2). Subsequently, the conducting layer 140 may be deposited with techniques such as chemical vapor deposition, physical vapor deposition, inkjet printing, or any other technique that is capable of realizing a conducting layer. The conducting layer 140 may have a thickness T4, for instance, in the range of 120-160 nm or a preferred value of 140 nm. The conducting layer 140 may be, for instance, made of polysilicon or metal. Even more specifically, doped polysilicon could settle the resistance layer, dopants like B, P, As, etc. may be used, or any conducting material, having a resistivity in the range of, for instance, 300-1000 Ohm/sq or with a preferred value of 600 Ohm/sq. It will be clear to those skilled in the art that the conducting layer 140 may be first deposited and then subjected to a planarization step, such as a CMP process, in order to obtain the shape illustrated in FIG. 7b.

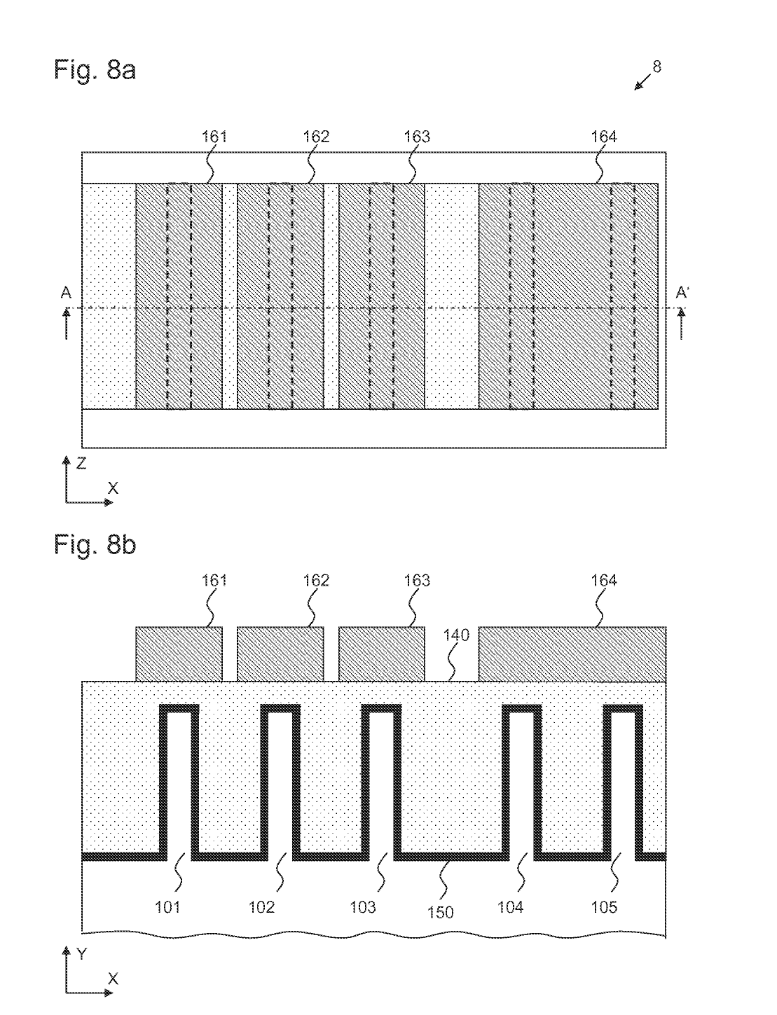

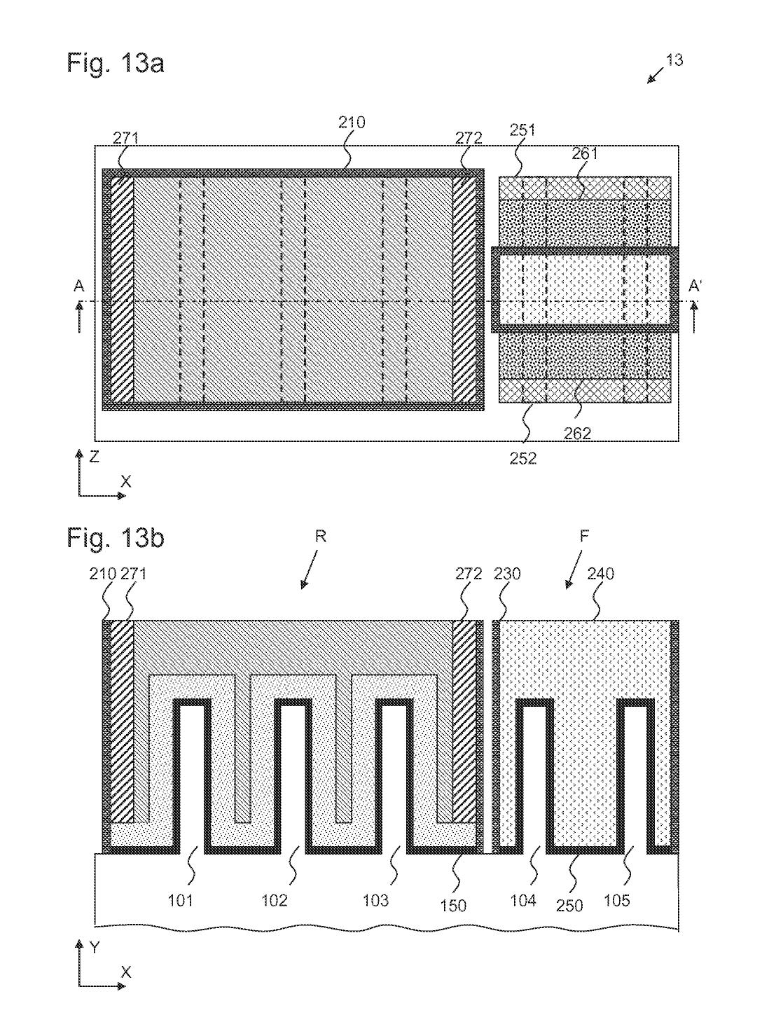

FIGS. 8a and 8b schematically illustrate a semiconductor structure 8 resulting from further processing of the semiconductor structure 7. The views along which FIGS. 8a and 8b have been taken correspond to the views of FIGS. 1a and 1b, respectively. As illustrated in FIGS. 8a and 8b, a mask 161-164, in particular a hardmask, may be realized on the conducting layer 140. Here, the hardmask is positioned with respect to the fins 101-105 so that openings of the mask correspond to the location of subsequent vertical trenches in the conducting layer 140, between adjacent fins. Additionally, the mask 161-164 may be structured so as to realize the trenches only between some of the fins 101-105 for the subsequent realization of the meander resistor. In the particular example illustrated in FIGS. 8a and 8b, the parts 161-163 of the mask 161-164 are used in order to open trenches between fins 101-102 and 102-103, which will be used for the subsequent realization of the meander resistor R (see FIG. 13b). On the other hand, the part 164 of the mask 161-164 is used for covering fins 104 and 105 which will be used for the subsequent realization of a FinFET transistor. It should, however, be noted that the illustrated implementation is an example only and that the co-presence of the meander resistor R and of a FinFET transistor F (see FIG. 13b) in the semiconductor structure is only provided as an advantageous example of how the present invention may be implemented so as to realize multiple structures with a single process flow. However, the present invention is not limited thereto and the meander resistor R could be implemented alone, independently of the presence of any FinFET transistor F, which may be realized either before or after the realization of the resistor R or may not be realized at all in the semiconductor structure.

Additionally, although in the illustrated example of FIGS. 8a and 8b, a mask 161-164 is used for the opening of the trenches within the conducting material 140, the present invention is not limited thereto. Alternatively, or in addition, a sidewall image transfer process, such as the one illustrated by FIGS. 1a to 5b, may be employed instead, in order to realize the trenches within the conducting material 140, particularly if the width of the trenches is smaller than the minimum width achievable by a photolithographic step realizing the mask 161-164.

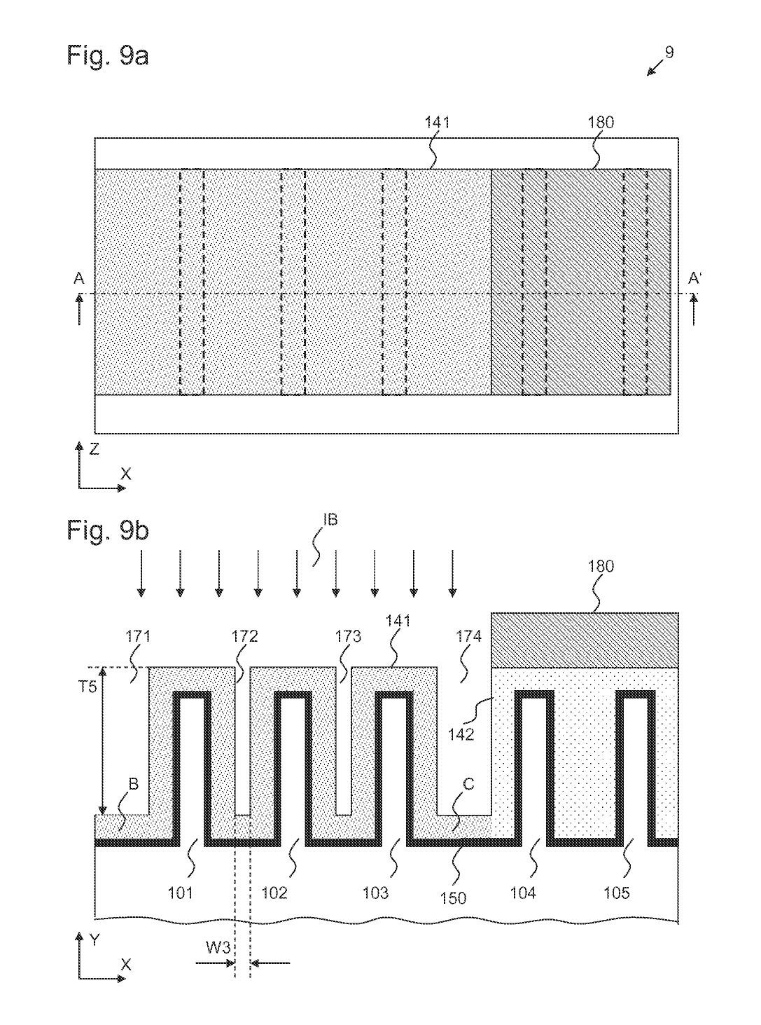

FIGS. 9a and 9b schematically illustrate a semiconductor structure 9 resulting from further processing of the semiconductor structure 8. The views along which FIGS. 9a and 9b have been taken correspond to the views of FIGS. 1a and 1b, respectively. FIGS. 9a and 9b illustrate a semiconductor structure 9 resulting from the semiconductor structure 8 after trenches 171-174 have been realized in the conducting material 140 thanks to the presence of openings in the mask 161-164. In particular, the trenches 171-174 may have a thickness T5, for instance, in the range of 80-120 nm or with a preferred value of 100 nm. Additionally, the trenches, in particular trenches 172 and 173 in between neighboring fins, may have a width W3, for instance, in the range of 10-60 nm or with the preferred value of 20 nm.

Moreover, illustrated in FIGS. 9a and 9b is an ion implantation, schematically depicted by arrows IB, performed on the conductive layer 140 left exposed after the etching process realizing the trenches 171-174 and after the mask 161-164 has been removed. In some embodiments, P, As or similar materials could be implanted, in concentrations such as 1-10 E14 1/cm² and energy values such as 3-10 keV. In some embodiments, it can be guaranteed that the implant on the top of the resistor is also the same on the bottom as the RTA will diffuse it into a very uniform state in the layer. If not, resistivity can be computed, for instance, by using Fick's law, Gaussian distribution, SRIM or similar approaches. Thanks to this doping step, the conductive layer 140 is converted into a meander resistive layer 141. Conversely, thanks to the presence of a mask 180, the ion implant IB is not performed in the conducting layer 140 being placed underneath the mask 180, thus resulting in conducting layer 142 having substantially the same characteristics as conducting layer 140.

In particular, due to the ion implant IB, the meander resistive layer 141 may have a resistance, for instance, in the range of 300-1000 Ohm/sq or with a preferred value of 600 Ohm/sq. In this manner, although a single material is used at first for regions 141 and 142, namely conducting material 140, the regions 141 and 142 can have different resistivity values with respect to each other. The ion implant IB is, however, not necessary and the invention could be carried out as well without it. In such embodiments, the resistor would be made of the same material as conducting layer 140.

Although the mask 180 has been defined as a new mask compared to the mask 161-164, the present invention is not limited thereto and, in the specific example of FIGS. 9a and 9b, the mask 180 could correspond to part 164 of the mask 161-164, which has not been removed during the etching process removing parts 161-163 of the mask 161-164 after the realization of the trenches 171-174.

At this manufacturing step, the vertically meandering resistor can be considered to be already realized. In particular, thanks to the presence of the resistive layer 141 having a vertically developing meander structure based on the supporting geometry of the fins 101-103, a resistor going from point B to point C is present in the semiconductor structure 9. Advantageously, the resistor occupies a reduced surface area of the semiconductor structure 9 along directions X and Z thanks to the vertical extension in the Y direction of the fins 101-103 on top of which the resistor is realized. In this manner, in a small surface area of the semiconductor structure 9, it is possible to realize a resistor having an area substantially wider than the surface area it occupies on the wafer.

As will be clear to those skilled in the art, the thickness of the vertically meandering resistive layer 141 may be controlled by controlling the width W3 of the trenches 171-174. Still additionally, it may be controlled by controlling the thickness in the Y direction of the meander resistive layer 141. This may be done, for instance, by controlling the duration of the etching step resulting in the depth of the trenches 171-174 and by subsequently proceeding to a planarization of the meander resistive layer 141 along direction X following the removal of the mask 161-164. Still additionally, the thickness in the Y direction of the meander resistive layer 141, particularly on the region above the fins 101-103, may also be controlled by controlling the thickness T4 (see FIG. 7b) of the conducting layer 140 with relation to the thickness T3 (see FIG. 6b) of the fins 101-105.

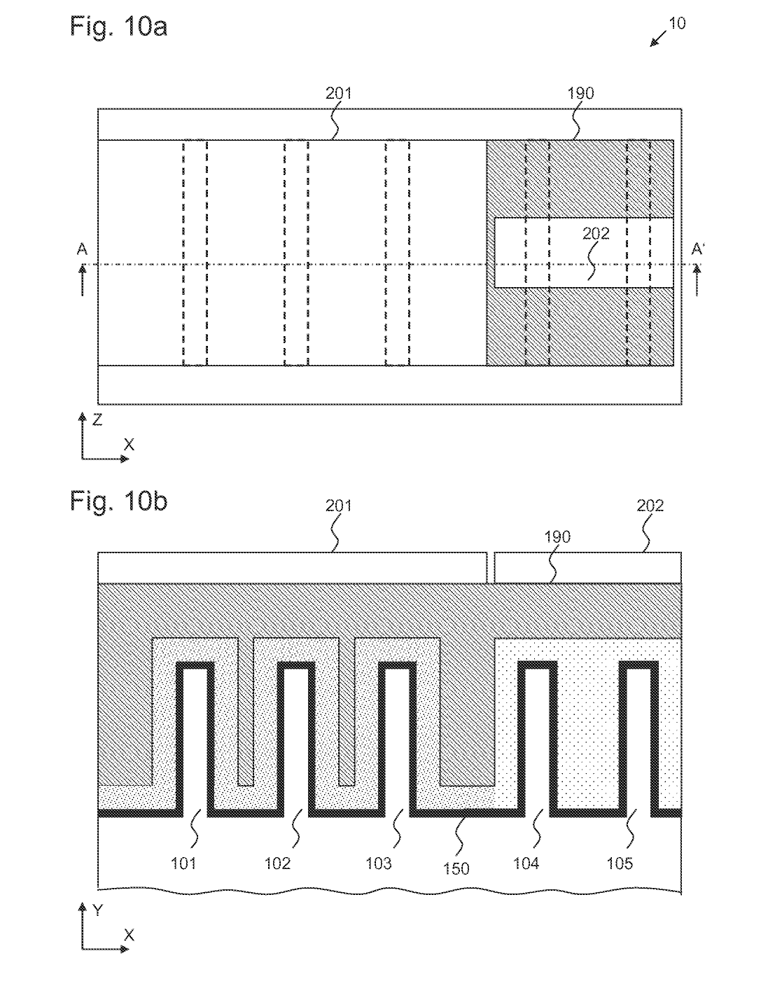

FIGS. 10a and 10b schematically illustrate a semiconductor structure 10 resulting from further processing of the semiconductor structure 9. The views along which FIGS. 10a and 10b have been taken correspond to the views of FIGS. 1a and 1b, respectively. The semiconductor structure 10 illustrated in FIGS. 10a and 10b differs from the semiconductor structure 9 due to the removal of the mask 180 protecting part of the semiconductor structure 9 from the ion implantation IB and due to the deposition of an insulating layer 190, on top of which a mask 201-202 is realized. The insulating layer could be, for instance, silicon nitride (SiN) or SiO2. Due to the presence of the mask, in subsequent manufacturing steps, the region containing the FinFET F can be further modified, while the region containing the resistor R is protected by the mask.

Generally, in an embodiment, the FinFET itself can then subsequently be built based on a replacement metal gate flow or a gate first, where the insulation layer will protect the resistor, and, on the FinFET areas, the hard mask/insulation layer will be removed for the process steps that are necessary only for the FinFET structure.

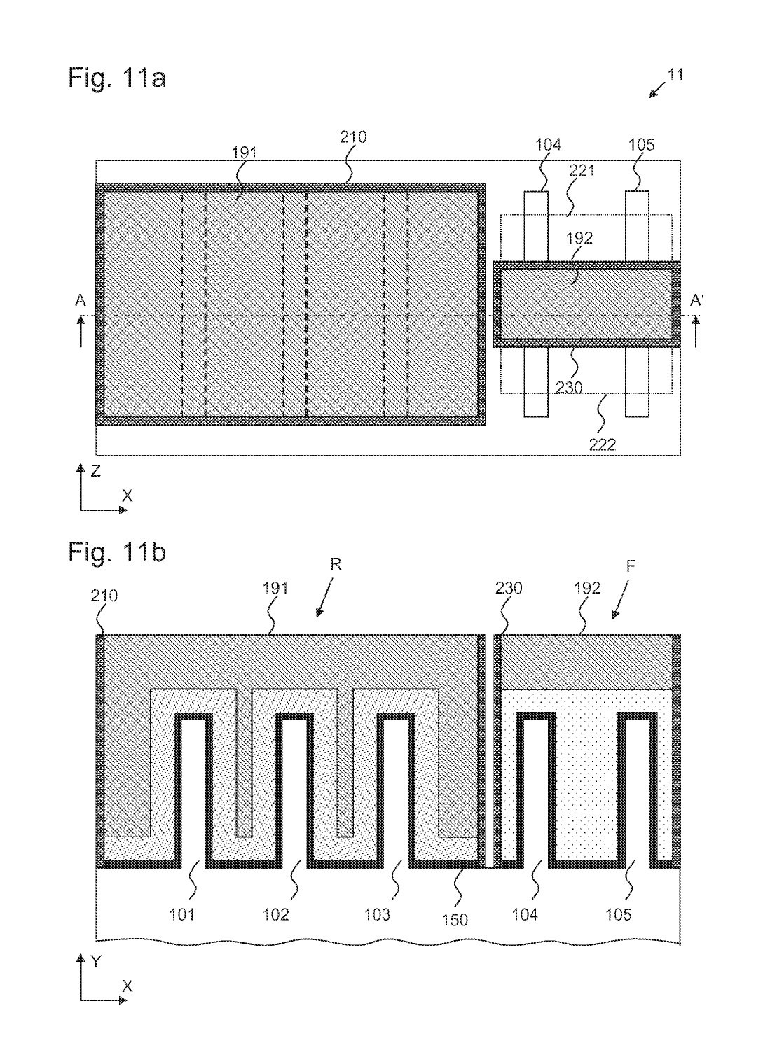

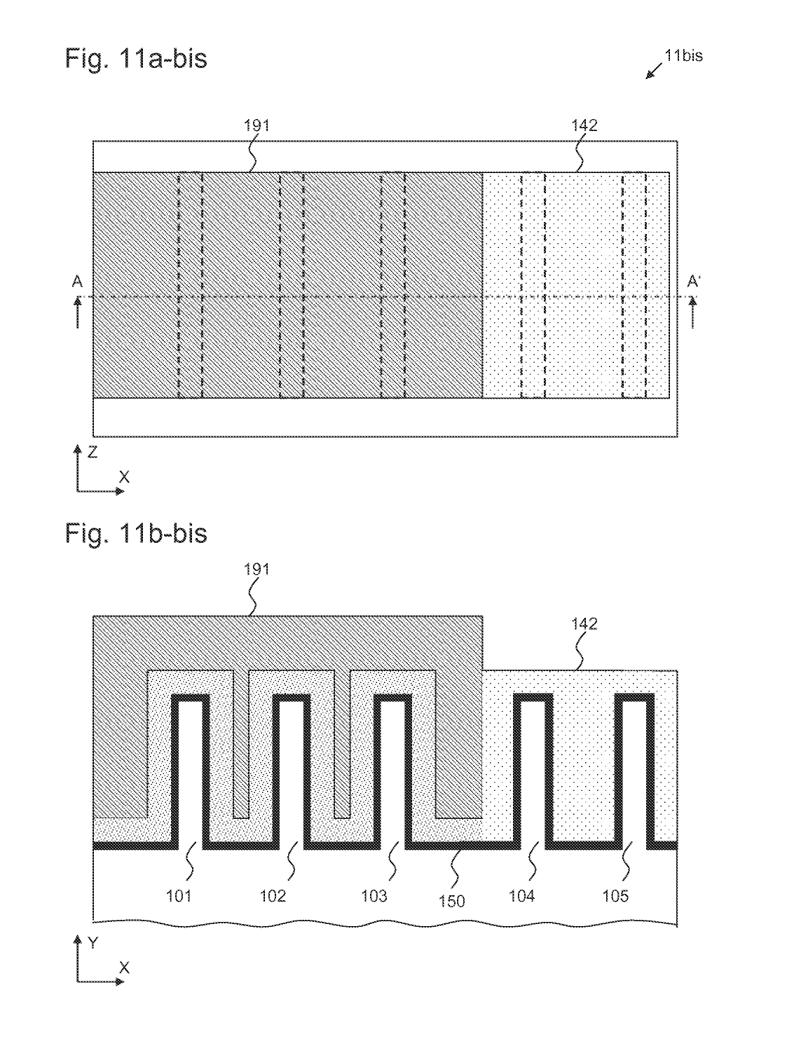

FIGS. 11a and 11b schematically illustrate a semiconductor structure 11 resulting from further processing of the semiconductor structure 10. The views along which FIGS. 11a and 11b have been taken correspond to the views of FIGS. 1a and 1b, respectively. In particular, in the semiconductor structure 11, the part of the insulating layer 190 not covered by the mask 201-202 has been removed and the mask 201-202 has been etched away. In this manner, regions 191 and 192 are left from the insulating layer 190. The region 191 insulates the resistor R from the external environment and provides electrical insulation between neighboring vertical surfaces of the resistor R which may, in the absence of any material therebetween, touch each other during time, for instance because of electron migration, thus changing the value of the resistor R. The region 192 can be used to protect the underlying conducting layer 142 during a subsequent realization of regions 221 and 222, the position of which is schematically represented by dashed lines in FIG. 11a. Regions 221 and 222 can comprise, for instance, SiC, or SiGe, Si for realizing the source and drain of the FinFET F.

Also illustrated in FIGS. 11a and 11b are sidewall spacers 210 and 230. Although illustrated as surrounding the entire regions 191 and 192, the present invention is not limited thereto. In particular, the sidewall spacer should be provided along the X direction between the source and the channel of the transistor, as well as between the drain and the channel. The presence of the sidewall spacer 230 also along the Z direction, as well as the presence of the spacer 210, is only an exemplary embodiment in which the sidewall spacer has been realized as surrounding the regions 191 and 192 for process flow integration purposes. The thickness of the sidewall spacers 210 and 230 could be in the region of 10-50 nm. The depth along the Y direction of the spacers 210 and 230 could be, as illustrated, substantially reaching the bottom of the fins 101-105. In general, any depth that allows separation of the drain/source region from the channel region of the FinFET may be used.

In this manner, the finalization of resistor R can be completed by connecting elements thereto, particularly to points B and C illustrated in FIG. 9b. At the same time, for the FinFET F, conducting material 142 may be maintained as a gate material, and the remaining parts of the FinFET F, such as source, drain, spacers and contacts, can be realized.

FIGS. 11a-bis and 11b-bis schematically illustrate a semiconductor structure 11bis resulting from further processing of the semiconductor structure 10. The views along which FIGS. 11a-bis and 11b-bis have been taken correspond to the views of FIGS. 1a and 1b, respectively. The semiconductor structure 11bis is an alternative to the semiconductor structure 11. In particular, the semiconductor structure 11bis is obtained from the semiconductor structure 10 in cases where only the mask 201 is present, while the mask 202 is absent. In this way, the insulating layer 190 is removed over the region of the FinFET F leaving only the insulating region 191 covering the resistor R. Thanks to this approach, the conducting material 142 can be accessed for further processing.

Generally, this is mainly valid for an n gate first approach aiming to build a FinFET on an HKMG first scheme, where the poly can be removed immediately after the resistor hard mask. For the full replacement gate process, this poly can be used as a dummy poly and can be patterned in a standard easy way.

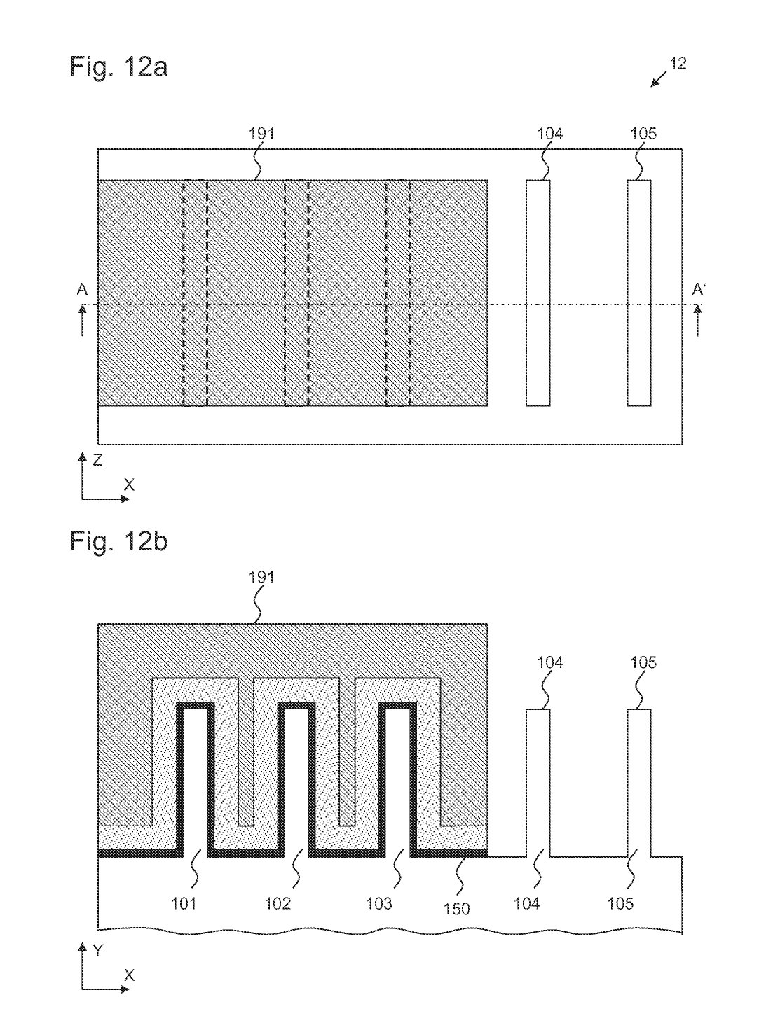

FIGS. 12a and 12b schematically illustrate a semiconductor structure 12 resulting from further processing of the semiconductor structure 11bis. The views along which FIGS. 12a and 12b have been taken correspond to the views of FIGS. 1a and 1b, respectively. Here, in the semiconductor structure 12, the conducting layer 142 and the insulating layer 150 are removed, thereby leaving the fins 104 and 105 in the FinFET F region open for further processing, illustrated in FIGS. 13a and 13b. In particular, in some embodiments, in the FinFET region, the implants could be done, for instance the gate doping, the gate oxide can be deposited, followed by an HKMG process, a dummy gate and a replacement gate. In the replacement gate process, in the middle of the line, the dummy poly can get removed and the gate will be re-filled with the HK and a work-function material, as well as the metal gate material.

FIGS. 13a and 13b schematically illustrate a semiconductor structure 13 resulting from further processing of the semiconductor structure 12. The views along which FIGS. 13a and 13b have been taken correspond to the views of FIGS. 1a and 1b, respectively. As illustrated in FIGS. 13a and 13b, an insulating layer 250 is realized over the fins 104 and 105, for instance by using a high-k material. On top of the insulating layer 250, a gate can then be deposited, for instance by using a metal gate. Additionally, source 262 and drain 261 are also realized over fins 104 and 105. Source 262 and drain 261 could be realized, for instance, by SiGe, or SiC, or a combination thereof. On top of the source 262, a source contact 252 can also be realized. Similarly, on top of the drain 251, a drain contact 261 can also be realized.

In some embodiments, re-building the FinFET with new layers instead of using the layers 150 and 142 can optionally be preferred, in order to make the device more versatile from a technology integration point of view.

In the resistor R, contacts 271 and 272 are also realized, for accessing the resistor R. Such contacts, although not illustrated, can also be realized for the resistor R in FIG. 11b.

Alternatively, although not illustrated, the end C of the resistor can be directly connected to the gate, source or drain of the FinFET F, while the end B can be connected via a contact 271 (see FIG. 9a for ends B and C).

Spacers 210 and 230 correspond to the same elements in FIGS. 11a and 11b. Also in this embodiment, the same considerations done for the embodiment of FIGS. 11a and 11b apply.

In the above-described embodiment, the height T3 (see FIG. 6b) of the fins 101-103 resulting in the resistor R is equal to the height T3 of the fins 104 and 105 resulting in the FinFET F. The present invention is, however, not limited thereto. Alternatively, or in addition, the height of the fins in the resistor R could be different from the height of the fins in the FinFET F. For instance, the fins 101-103 could have a bigger height than the fins 104 and 105. This could be advantageous, for instance, in those cases where the thickness of the fins cannot be precisely controlled if a certain height is surpassed. Thus, for those fins for which the thickness must be precisely controlled, namely those of the FinFET F, the height may be lower than for those for which the thickness is a less sensitive parameter, namely those of the resistor R. The advantage in this case would be that the resistor R could extend further vertically into the substrate 100, thus occupying an area on the X and Z direction still further reduced. It will be clear to those skilled in the art that the opposite approach can also be implemented. Namely, having a height for the fins 104 and 105 higher than the height for the fins 101-103.

Still further, although all of fins 101-103 have been described above as having the same height, the present invention is not limited thereto. Alternatively, or in addition, some of the fins 101-103 could have heights different from some other of the fins 101-103. This could be, for instance, exploited when the etching of the fins is not the same for those on the periphery, such as 101 and 103, and for those in the center, such as 102. In this case, the difference of etching efficiency could be taken into account when determining the length of the resistor, instead of adding dummy fins outside of the fins 101 and 103 so as to equalize their height with that of fin 102.

Additionally, although the fins 101-105 have all been described as being made of semiconductor material, the present invention is not limited thereto. In particular, fins used for the implementation of the resistor, such as the fins 101-103, do not necessarily need to be made of semiconductor material and could be made as well of insulating material, conducting material or a combination of any of those. One advantage of using a semiconductor material for all fins 101-105 consists in that the fins can all be realized at a single stage and subsequently be used both for the realization of the resistor R and the FinFET F.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1-20. (canceled)

21. A method, comprising:
forming a plurality of fins in a semiconductor substrate using a common patterning process;
forming a resistor comprising a resistive layer positioned above a subset of the plurality of fins, wherein said resistive layer comprises trenches filled with a first insulating layer in regions between adjacent fins;
forming first and second contacts connected to respective ends of said resistive layer; and
forming a transistor comprising a gate positioned above at least one fin of the plurality of fins other than those in the first subset of the plurality of fins.

22. The method of claim 21, wherein forming said resistive layer comprises:
forming a conductive layer above said plurality of fins;
forming a mask above said conductive layer; and
etching said conductive layer using said mask to define said trenches in said conductive layer.

23. The method of claim 22 further comprising forming a second insulating layer above said plurality of fins prior to forming said conductive layer.

24. The method of claim 23, wherein said gate comprises a portion of said second insulating layer and a portion of said conductive layer.

25. The method of claim 23, further comprising:
removing a portion of said conductive layer disposed above said at least one fin;
removing a portion of said second insulating material layer from above said at least one fin; and
forming a replacement gate including a second insulating layer and a second conductive layer above said at least one fin.

26. The method of claim 22, further comprising doping said conductive layer.

27. The method of claim 26, wherein doping said conductive layer comprises doping said conductive layer with boron, phosphorous or arsenic.

28. A semiconductor device, comprising:
a first plurality of trenches defined in a semiconductor substrate, the first plurality of trenches defining a plurality of fins;
a resistive layer positioned above a first subset of the plurality of fins, the resistive layer having a second plurality of trenches defined therein, wherein the second plurality of trenches are positioned at least partially in the first group of the trenches and filled with an insulating layer;
first and second resistor contacts connected to respective first and second ends of said resistive layer;
a gate structure for a transistor positioned above at least one of the plurality of fins other than those in the first subset of the plurality of fins.

29. The semiconductor device of claim 28, wherein the resistive layer is positioned around side surfaces and a top surface of each of the fins in the first subset and above a bottom surface of each of the trenches associated therewith.

30. The semiconductor device of claim 28, wherein the resistive layer has a substantially uniform topography.

31. The semiconductor device of claim 28, further comprising a conformal layer of insulating material positioned on the first subset of the plurality of fins and in the trenches associated therewith beneath the resistive layer.

32. The semiconductor device of claim 28, wherein said conformal layer of insulating material has a thickness in the range of 3-10 nm.

33. The semiconductor device of claim 32, wherein said conformal layer of insulating material has a thickness of approximately 4 nm.

34. The semiconductor device of claim 28, wherein said gate and said resistive layer comprise a same material.

35. The semiconductor device of claim 34, wherein a material of said gate comprises at least one of polysilicon or metal.

36. The semiconductor device of claim 28, wherein said resistive layer further comprises a doping material.

37. The semiconductor device of claim 35, wherein said doping material comprises at least one of boron, phosphorous or arsenic.

38. The semiconductor device of claim 28, wherein the resistive layer has a non-planar configuration.

39. The semiconductor device of claim 28, wherein the resistive layer a meandering shape in a vertical direction with respect to said semiconductor substrate.
